(19) United States
(12) Patent Application Publication
(10) Pub. No.: US 2026/0255479 A1
(43) Pub. Date: Aug. 27, 2026

(54) PRINTED CIRCUIT BOARD AND MANUFACTURING METHOD THEREOF

(71) Applicant: SAMSUNG ELECTRO-MECHANICS CO., LTD., Suwon-si (KR)

(72) Inventor: Jong Tae Park, Suwon-si (KR)

(73) Assignee: SAMSUNG ELECTRO-MECHANICS CO., LTD., Suwon-si (KR)

(21) Appl. No.: 19/313,665

(22) Filed: Aug. 28, 2025

(30) Foreign Application Priority Data
Feb. 24, 2025 (KR) 10-2025-0023798

(51) Int. Cl. H05K 1/09; H05K 3/10

(52) U.S. Cl. CPC H05K 1/09; H05K 3/10; H05K 2201/0317; H05K 2201/0323; H05K 2201/0326; H05K 2201/0329; H05K 2201/0338; H05K 2203/0152

(57) ABSTRACT

A printed circuit board according to an embodiment may include an insulating layer, a first circuit pattern buried in the insulating layer such that one surface thereof is exposed on one surface of the insulating layer, a second circuit pattern disposed on the other surface, which is opposite to the one surface of the insulating layer, the second circuit pattern protruding from the other surface, a surface conductive layer disposed on at least a portion of the first circuit pattern, the surface conductive layer being made of a material different from that of the first circuit pattern, a surface treatment layer on the surface conductive layer, and a solder resist layer disposed on the one surface to expose the surface treatment layer.

### CROSS-REFERENCE TO RELATED APPLICATION

This application claims priority to and the benefit of Korean Patent Application No. 10-2025-0023798 filed with the Korean Intellectual Property Office on February 24, 2025, the entire contents of which are incorporated herein by reference.

### BACKGROUND

### a. Technical Field

The present disclosure relates to a printed circuit board and a manufacturing method thereof.

### b. Description of the Related Art

Demand for high-performance logic semiconductors is increasing in technical fields such as AI and automatic driving vehicles, and package technology is also changing.

A pad for electrical connection with a semiconductor chip is disposed on the outermost layer of a printed circuit board on which the semiconductor chip is mounted. A surface treatment layer is disposed on the pad to prevent oxidation thereof and improve bonding property with solder.

A plating lead is required to form the surface treatment layer through electro-plating, but the area occupied by the plating lead can be constraints of circuit design.

### SUMMARY

Embodiments of the present disclosure attempt to provide a printed circuit board and a manufacturing method thereof capable of forming a surface treatment layer without a plating lead.

In addition, embodiments of the present disclosure attempt to provide a printed circuit board manufactured by a simplified process without a plating lead forming process and a method of manufacturing the same.

According to an embodiment, a printed circuit board may include an insulating layer, a first circuit pattern buried in the insulating layer such that a first surface of the insulating layer does not cover a first surface of the first circuit pattern, a second circuit pattern disposed on a second surface of the insulating layer, is the second surface being opposite to the first surface of the insulating layer, and the second circuit pattern protruding from the second surface, a surface conductive layer disposed on at least a portion of the first circuit pattern, the surface conductive layer including a first material different from a second material included in the first circuit pattern, a surface treatment layer on the surface conductive layer, and a solder resist layer disposed on the first surface of the insulating layer to expose the surface treatment layer.

The surface conductive layer may protrude from the first surface of the insulating layer.

The first material may include a metal having an etch selectivity with respect to the second material. In this case, the first material may include nickel (Ni), and the second material may include copper (Cu).

The first material may include a non-metal conductive material.

The non-metal conductive material may include graphite or a conductive polymer.

The non-metal conductive material may include graphite.

The non-metal conductive material may include a conductive polymer.

The conductive polymer may include at least one polymer selected from polyacetylene, polyphenylenevinylene, polypyrrole, and polythiophene. The surface treatment layer may include gold (Au).

According to an embodiment, a manufacturing method of a printed circuit board may include forming a surface seed layer on a carrier, forming a first circuit pattern on the surface seed layer, forming an insulating layer on the surface seed layer to cover the first circuit pattern, forming a second circuit pattern on the insulating layer, removing the carrier, forming a surface treatment layer on the surface seed layer, the surface treatment layer overlapping at least a portion of the first circuit pattern, forming a surface conductive layer interposing the first circuit pattern and the surface treatment layer by removing a portion of the surface seed layer exposed by the surface treatment layer, and forming a solder resist layer exposing the surface treatment layer on the insulating layer.

The surface seed layer may include a metal having an etch selectivity with respect to a material included in the first circuit pattern. In this case, the metal may include nickel and the material included in the first circuit pattern may include copper.

The surface seed layer may include a non-metal conductive material.

The non-metal conductive material may include graphite or a conductive polymer

The forming of the surface treatment layer may include forming a mask pattern having an opening overlapping at least the portion of the first circuit pattern on the surface seed layer, and forming an electro-plating layer on a portion of the surface seed layer exposed by the opening.

The electro-plating layer may include gold (Au).

According to embodiments, the surface treatment layer may be formed on the outermost pad without a separate plating lead. Therefore, the entire printed circuit board manufacturing process may be simplified and it is possible to avoid the constraints of circuit design due to the area occupied by the plating lead

However, it is obvious that the effects of the embodiments are not limited to the above-described effects and may be variously extended without departing from the concept and scope of the present disclosure.

### BRIEF DESCRIPTION OF THE DRAWINGS

FIG. 1 is a cross-sectional view illustrating a printed circuit board according to an embodiment.

FIGS. 2 to 7 are cross-sectional views illustrating a manufacturing method of a printed circuit board according to an embodiment.

### DETAILED DESCRIPTION

Hereinafter, various embodiments of the present disclosure will be described in detail so that a person of ordinary skill in the technical field to which the present disclosure belongs can easily implement it with reference to the accompanying drawings. The present disclosure may be implemented in various different forms and is not limited to the embodiments described herein.

In order to clearly describe the present disclosure, parts unrelated to the description are omitted in the drawings, and the same reference numerals are designated to the same or similar elements throughout the specification.

In addition, accompanying drawings are provided only in order to allow embodiments disclosed in the present specification to be easily understood and are not to be interpreted as limiting the technical concept disclosed in the present specification, and it is to be understood that the present disclosure includes all modifications, equivalents, and substitutions without departing from the scope and concept of the present disclosure.

Furthermore, the size and thickness of each element shown in the drawing are arbitrarily shown for convenience of explanation, and present disclosure is not necessarily limited to those shown. In the drawings, the thickness of layers, films, panels, regions, etc., are exaggerated for clarity.

Furthermore, it will be understood that when an element such as a layer, film, region, or substrate is referred to as being “on” another element, it can be directly on the other element or intervening elements may also be present. On the contrary, when an element is referred to as being “directly on” another element, there are no intervening elements present. Furthermore, in the specification, the word “on” or “above” means positioned on or below the object portion and does not necessarily mean positioned on the upper side of the object portion based on a gravitational direction.

Unless explicitly described to the contrary, the word “comprise” and variations such as “comprises” or “comprising” will be understood to imply the inclusion of stated elements but not the exclusion of any other elements.

Furthermore, throughout the specification, "connected" means that two or more elements are not only directly connected, but two or more elements may be connected indirectly through other elements, physically connected as well as being electrically connected, or it may be referred to by different names depending on the location or function but may mean integral.

Hereinafter, embodiments will be described in detail with reference to the drawings.

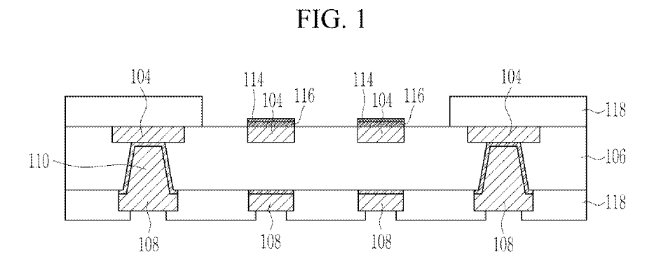

FIG. 1 is a cross-sectional view illustrating a printed circuit board according to an embodiment..

Referring to FIG. 1, the printed circuit board according to the embodiment may include an insulating layer 106. The insulating layer may be a Ajinomoto Build-up Film (ABF). Although the insulating layer 106 is illustrated as one layer in FIG. 1, the insulating layer 106 may include a plurality of insulating layers in another embodiment. When the insulating layer 106 includes a plurality of insulating layers, some of the insulating layers may be prepregs manufactured by impregnating glass fibers with a thermosetting resin or a thermoplastic resin. In some cases, at least one of the insulating layers may be photo-imagingable dielectric (PID).

A first circuit pattern 104 may be disposed on one surface of the insulating layer. One surface of the first circuit pattern 104 may be exposed from the insulating layer 106 and the other surfaces may be buried in the insulating layer 106. For example, as illustrated in FIG. 1, when the cross section of the first circuit pattern 104 has four surfaces, one surface may be exposed from the insulating layer 106 and the other three surfaces may be buried in the insulating layer 106. The first circuit pattern 104 may be copper (Cu).

A second circuit pattern 108 may be disposed on the other surface, which is opposite to the one surface of the insulating layer 106. The second circuit pattern 108 may be disposed to protrude from the other surface of the insulating layer 106. Some of the second circuit patterns 108 may be connected to some of the first circuit pattern 104 by a via 110 penetrating the insulating layer 106. The second circuit pattern 108 and the via 110 may be a copper (Cu). The via 110 may have a reduced cross-sectional area along a height direction from the other surface to the one surface of the insulating layer 106. That is, among the cross-sectional areas of the via 110 in the direction perpendicular to the height direction, the cross-sectional area closest to the one surface of the insulating layer 106 may be smaller than the cross-sectional area closest to the other surface of the insulating layer 106.

In another embodiment, when the insulating layer 106 includes a plurality of insulating layers, circuit patterns may be disposed on each insulating layer, and some of the circuit patterns may be connected to each other by vias penetrating each insulating layer. In this case, the vias may have a reduced cross-sectional area along the height direction, such as via 110 illustrated in FIG. 1.

A solder resist layer 118 may be disposed on the one surface and the other surface of the insulating layer 106. The solder resist layer 118 may partially expose the second circuit pattern 108. In addition, the solder resist layer 118 may expose some of the first circuit pattern 104.

A surface conductive layer 116 and a surface treatment layer 114 may be sequentially disposed on the first circuit pattern 104 exposed by the solder resist layer 118. The surface conductive layer 116 may protrude from the one surface of the insulating layer 106. The surface conductive layer 106 may be a metal having an etch selectivity with respect to the first circuit pattern 104. That is, with respect to a specific etchant, the surface conductive layer 116 may be etched, while the first circuit pattern 104 may not be etched or may be etched at a very low speed. On the contrary, with respect to another etchant, the first circuit pattern 104 may be etched, while the surface conductive layer 116 may not be etched or may be etched at a very low speed. When the first circuit pattern 104 is copper (Cu), the surface conductive layer 116 may be nickel (Ni). In another embodiment, the surface conductive layer 116 may be a non-metal conductive material such as graphite or a conductive polymer. The conductive polymer may be polyacetylene, polyphenylenevinylene, polypyrrole, or polythiophene. The etch selectivity may be measured by subjecting the materials to the etching process, measuring the etch depth using profilometry, scanning electron microscopy (SEM), or ellipsometry to measure the amount of material removed from each sample after etching, calculating the etch rate by dividing the measured etch depth by the etch time to obtain the etch rate for each material, and obtaining etch selectivity as a ratio of the etch rates for each material. Other methods and/or tools appreciated by one of ordinary skill in the art, even if not described in the present disclosure, may also be used.

The surface treatment layer 114 may be gold (Au).

According to the present embodiment, the surface conductive layer 116 and the surface treatment layer 114 may be disposed on the first circuit pattern 104, so that the first circuit pattern 104 may be effectively protected even if exposed by the solder resist layer 118. In addition, a plating lead for forming the surface treatment layer 114 may not be required, thereby restrictions on circuit design can be avoided.

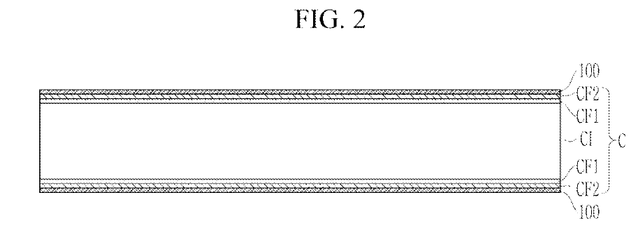

FIGS. 2 to 7 are cross-sectional views illustrating a manufacturing method of a printed circuit board according to an embodiment.

Referring to FIG. 2, the surface seed layer 100 may be formed on the carrier C. The carrier C may include a first copper foil layer CF1 and a second copper foil layer CF2 sequentially stacked on both surfaces of a carrier insulating layer CI. The surface seed layer 100 may be formed on the second copper foil layer CF2 through electro-plating. The surface seed layer 100 may be a metal having an etch selectivity with respect to the second copper foil layer CF2 and the first circuit pattern 104 to be described later. That is, with respect to a specific etchant, the surface seed layer 100 may be etched, while the second copper foil layer CF2 and the first circuit pattern 104 may not be etched or may be etched at a very low speed. On the contrary, with respect to another etchant, the second copper foil layer CF2 and the first circuit pattern 104 may be etched, while the surface seed layer 100 may not be etched or may be etched at a very low speed. When the second copper foil CF2 and the first circuit pattern 104 is copper (Cu), the surface seed layer 100 may be nickel (Ni). In another embodiment, the surface seed layer 100 may be a non-metal conductive material such as graphite or a conductive polymer. In this case, the surface seed layer 100 may be formed through printing or coating process. The conductive polymer may be polyacetylene, polyphenylenevinylene, polypyrrole, or polythiophene.

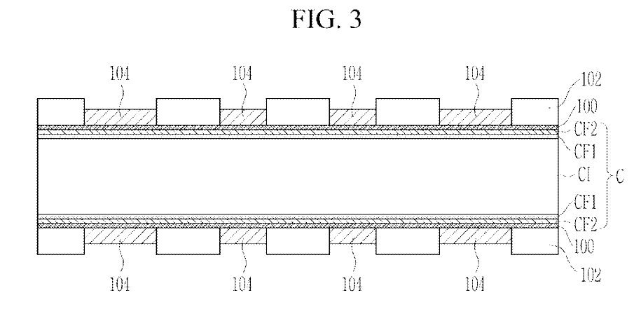

Referring to FIG. 3, a first mask 102 may be formed on the surface seed layer 100. The first mask 102 may be formed by laminating a photosensitive resin film on the surface seed layer 100 and then performing photolithography. Thereafter, the first circuit pattern 104 may be electro-plated on the surface seed layer 100 exposed by the first mask 102 using the surface seed layer 100 as a plating seed. The first circuit pattern 104 may be formed of copper (Cu).

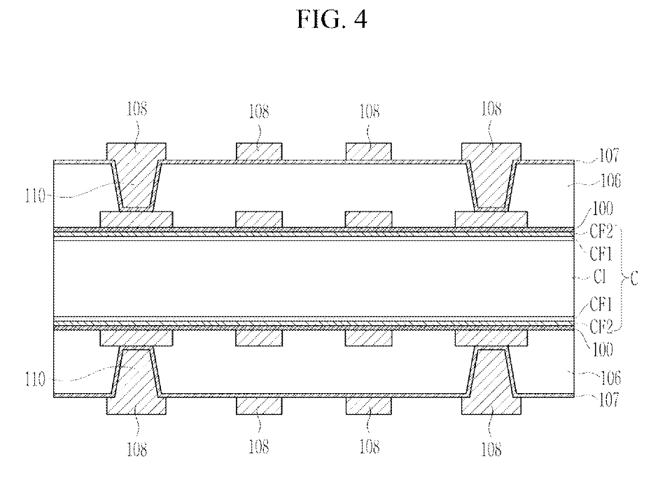

Referring to FIG. 4, the insulating layer 106 may be formed on the surface seed layer 100 to cover the first circuit pattern 104. The insulating layer 106 may be formed by laminating Ajinomoto Build-up Film (ABF) on the surface seed layer 100 and applying heat and pressure thereto. Thereafter, the insulating layer 106 may be laser processed or drilled to form a via hole exposing a portion of the first circuit pattern 104. A circuit seed layer 107 may be formed on the insulating layer 106 in which the via hole is formed and the first circuit pattern 104 exposed by the via hole through electroless plating process. The via 110 filling the via hole and the second circuit pattern 108 on the insulating layer 106 may be formed by an electro-plating process using the circuit seed layer 107 as a plating seed. A plating mask that exposes the area where the second circuit pattern 108 is to be formed may be formed on the circuit seed layer 107 before the electro-plating process. The circuit seed layer 107 and the second circuit pattern 108 may be formed of copper (Cu).

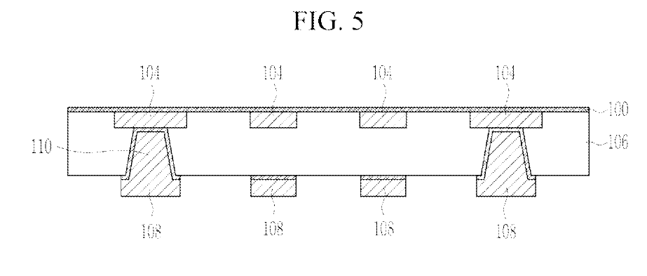

Referring to FIG. 5, the first copper foil layer CF1 and the second copper foil layer CF2 may be separated to remove the remaining portions of the carrier C except for the second copper foil layer CF2. As a result, two coreless stacks may be formed, and hereinafter, one of them will be illustrated and described.

After removing the remaining portions of the carrier C, the second copper foil layer CF2 may be etched to be removed. Since the surface seed layer 100 has an etch selectivity with respect to the second copper foil layer CF2, the surface seed layer 100 may not be etched or may be etched at a very low speed while the second copper foil layer CF2 is etched. Meanwhile, while the second copper foil layer CF2 is etched, the circuit seed layer 107 exposed by the second circuit pattern 108 may also be etched.

As illustrated in FIG. 5, the first conductive pattern 104 may be buried in the insulating layer 106 such that one surface thereof is exposed on the one surface of the insulating layer 106. The second circuit pattern 108 may be formed on the other surface of the insulating layer opposite to the one surface of the insulating layer 106. The second circuit pattern 108 may protrude from the other surface. The circuit seed layer 107 remaining after etching may be interposed between the second conductive pattern 108 and the insulating layer 106.

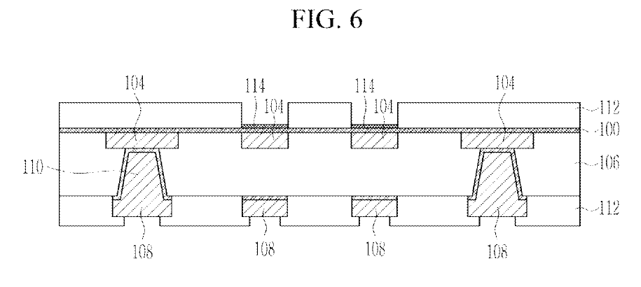

Referring to FIG. 6, a second mask 112 may be formed on the one surface and the other surface of the insulating layer 106. Specifically, the second mask 112 may be formed on the surface seed layer 100 on the one surface of the insulating layer 106 to have an opening at least partially overlapping some of the first circuit patterns 104. In addition, the second mask 112 may be formed to cover the entire other surface of the insulating layer 106. The second mask 102 may be formed by laminating a photosensitive resin film on the surface seed layer 100 and then performing photolithography.

Thereafter, the surface treatment layer 114 may be formed on the surface seed layer 100 exposed by the second mask 112. The surface treatment layer 114 may be formed by electro-plating gold (Cu) using the surface seed layer 100 as a plating seed.

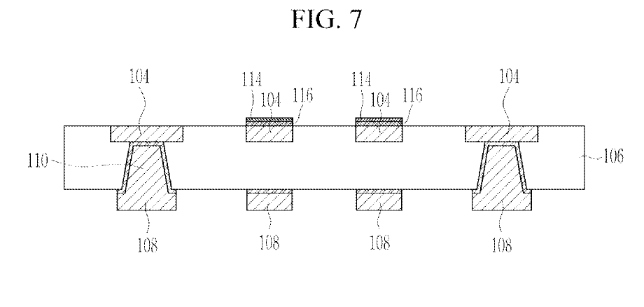

Referring to FIG. 7, after removing the second mask 112, the surface seed layer 100 exposed by the surface treatment layer 114 may be removed by etching. As a result, the surface conductive layer 116 interposed between the surface treatment layer 114 and the first circuit pattern 104 may be formed. The surface treatment layer 114 may be used as an etch mask while the surface seed layer 100 is etched. In addition, since the surface seed layer 100 may be a metal having an etch selectivity with respect to the first circuit pattern 104, the first circuit pattern 104 may not be etched or may be etched at a very low speed while the surface seed layer 100 is etched.

In another embodiment, when the surface seed layer 100 is formed of graphite or a conductive polymer, a portion exposed by the surface treatment layer 114 may be removed by dry etching such as plasma etching.

According to embodiments, the surface seed layer 100 used as a plating seed for electro-plating the first circuit pattern 104 may be used as a plating seed for electro-plating the surface treatment layer 114. Therefore, the process can be simplified by performing two electro-plating with one plating seed. In addition, by forming the surface treatment layer 114 without a separate plating lead, it is possible to avoid the constraints of circuit design due to the area occupied by the plating lead.

While embodiments of the present disclosure have been described above, the present disclosure is not limited thereto, and it is possible to perform various modifications within the scope of the claims, the detailed description, and the accompanying drawings, and it is natural that these modifications also fall within the scope of the present disclosure.

What is claimed is:

1. A printed circuit board comprising:
an insulating layer;
a first circuit pattern buried in the insulating layer such that a first surface of the insulating layer does not cover a first surface of the first circuit pattern;
a second circuit pattern disposed on a second surface of the insulating layer, the second surface being opposite to the first surface of the insulating layer, and the second circuit pattern protruding from the second surface;
a surface conductive layer disposed on at least a portion of the first circuit pattern, the surface conductive layer including a first material different from a second material included in the first circuit pattern;
a surface treatment layer on the surface conductive layer; and
a solder resist layer disposed on the first surface of the insulating layer to expose the surface treatment layer.

2. The printed circuit board of claim 1, wherein
the surface conductive layer protrudes from the first surface of the insulating layer.

3. The printed circuit board of claim 1, wherein
the first material includes a metal having an etch selectivity with respect to the second material.

4. The printed circuit board of claim 3, wherein
the first material includes nickel and the second material includes copper.

5. The printed circuit board of claim 1, wherein
the first material includes a non-metal conductive material.

6. The printed circuit board of claim 5, wherein
the non-metal conductive material includes graphite or a conductive polymer.

7. The printed circuit board of claim 5, wherein
the non-metal conductive material includes graphite.

8. The printed circuit board of claim 5, wherein
the non-metal conductive material includes a conductive polymer.

9. The printed circuit board of claim 8, wherein
the conductive polymer includes at least one polymer selected from polyacetylene, polyphenylenevinylene, polypyrrole, and polythiophene.

10. The printed circuit board of claim 1, wherein
the surface treatment layer includes gold (Au).

11. A manufacturing method of a printed circuit board comprising:
forming a surface seed layer on a carrier,
forming a first circuit pattern on the surface seed layer,
forming an insulating layer on the surface seed layer to cover the first circuit pattern,
forming a second circuit pattern on the insulating layer,
removing the carrier,
forming a surface treatment layer on the surface seed layer, the surface treatment layer overlapping at least a portion of the first circuit pattern,
forming a surface conductive layer interposing the first circuit pattern and the surface treatment layer by removing a portion of the surface seed layer exposed by the surface treatment layer, and
forming a solder resist layer exposing the surface treatment layer on the insulating layer.

12. The manufacturing method of claim 11, wherein:
the surface seed layer includes a metal having an etch selectivity with respect to a material included in the first circuit pattern.

13. The manufacturing method of claim 12, wherein
the metal includes nickel and the material included in the first circuit pattern includes copper.

14. The manufacturing method of claim 11, wherein
the surface seed layer includes a non-metal conductive material.

15. The manufacturing method of claim 14, wherein:
the non-metal conductive material includes graphite or a conductive polymer.

16. The manufacturing method of claim 11, wherein
the forming of the surface treatment layer comprises,
forming a mask pattern having an opening overlapping at least the portion of the first circuit pattern on the surface seed layer, and forming an electro-plating layer on a portion of the surface seed layer exposed by the opening.

17. The manufacturing method of claim 16, wherein:
the electro-plating layer includes gold (Au).
